(19) United States
(12) Patent Application Publication
(10) Pub. No.: US 2012/0249172 A1
(43) Pub. Date: Oct. 4, 2012

(54) ALIGNMENT SYSTEM FOR ELECTRONIC DEVICE TESTING

(75) Inventor: Matthew S. Cameron, Battle Ground, WA (US)

(73) Assignee: ELECTRO SCIENTIFIC INDUSTRIES, INC., Portland, OR (US)

(21) Appl. No.: 13/076,529

(22) Filed: Mar. 31, 2011

(51) Int. Cl. G01R 31/00

(52) U.S. Cl. 324/750.16

(57) ABSTRACT

An alignment system for aligning one or more devices under test with respect to a test station includes a carrier that is configured to carry the one or more devices under test, a conveyor that is configured to move the carrier in unison with the conveyor, and an alignment structure. The alignment structure is engageable with the carrier to move the carrier with respect to the conveyor to align at least one of the devices under test with respect to the test station.

### FIELD OF THE INVENTION

The disclosure relates to the field of electronic device testing and, more particularly, to an alignment system for aligning one or more electronic devices under test with respect to a test station.

### BACKGROUND

Many electronic devices are tested for electrical and optical properties during manufacturing by automated test systems. Typical automatic test systems use precision electrical or optical test equipment to find values associated with electrical and optical properties of a device and either accept, reject or sort it into an output category depending upon the measured values. For miniature devices, automatic test systems are often designed to handle bulk loads, where the manufacturing process creates a volume of devices that have substantially identical mechanical characteristics such as size and shape but differ in electrical or optical characteristics. It is common practice to build a volume of devices with electrical and optical properties that generally fall within a range and rely on testing to sort the devices into commercially useful groups with similar characteristics.

These devices are often supplied to the test equipment as containers filled with devices. Typically the test equipment must extract a single device from the bulk load of devices, orient the device and fixture it so the test equipment can perform the desired tests. Testing often requires probing the device, wherein electrical leads are brought into contact with device to permit signals and power to be applied to the device and to monitor responses to the inputs. Other tests involve measuring light output from optical devices such as LEDs in response to specific inputs. The task of the automatic test system is to determine the electrical or optical characteristics of devices and sort the devices into groups depending upon those characteristics.

### SUMMARY OF THE INVENTION

Embodiments of alignment systems for electronic device testing are taught herein.

One alignment system taught herein is adapted to align one or more devices under test with respect to a test station. The alignment system includes a carrier that is configured to carry the devices under test and a conveyor that is configured to move the carrier in unison with the conveyor. An alignment structure is engageable with the carrier to move the carrier with respect to the conveyor to align at least one of the devices under test with respect to the test station.

Another alignment system taught herein includes a carrier that is configured to carry one or more devices under test and a conveyor that is configured to move the carrier in unison with the conveyor in a first direction. A decoupling structure is positioned along the conveyor adjacent to the test station and is engageable with the carrier to partially decouple the carrier from the conveyor such that the carrier is moveable with respect to the conveyor in the first direction. An alignment structure is engageable with the carrier to move the carrier with respect to the conveyor to align at least one of the devices under test with respect to the test station when the carrier and the conveyor are partially decoupled.

Another alignment system taught herein includes a carrier that is configured to carry one or more devices under test. The carrier includes at least one locating feature. A conveyor is configured to move the carrier in unison with the conveyor in a first direction. A decoupling structure is positioned along the conveyor adjacent to the test station. The decoupling structure is engageable with the carrier to partially decouple the carrier from the conveyor such that the carrier is moveable with respect to the conveyor in the first direction. The decoupling structure partially decouples the carrier from the conveyor as the carrier arrives at the test station and recouples the carrier to the conveyor as the carrier departs the test station. An alignment structure is engageable with the locating feature of the carrier to move the carrier with respect to the conveyor to align at least one of the devices under test with respect to the test station.

### BRIEF DESCRIPTION OF THE DRAWINGS

The description herein makes reference to the accompanying drawings wherein like reference numerals refer to like parts throughout the several views, and wherein:

FIG. 1 is a top down view showing one embodiment of an automated test system;

FIG. 2 is a perspective view of one embodiment of a carrier of the automated test system of FIG. 1;

FIG. 3 is a cross-sectional end view showing the carrier of FIG. 2 and a conveyor of the automated test system of FIG. 1;

FIG. 4 is a side view showing the carrier of FIG. 2 and a cleat of the conveyor of FIG. 3;

FIG. 5 is an illustration showing alignment of an electronic device with respect to a test station of the automated test system of FIG. 1;

FIG. 6 is a perspective view of one embodiment of an alignment structure of the automated test system of FIG. 1;

FIG. 7 is a front view of the alignment structure of FIG. 6;

FIG. 8 is a side view of the alignment structure of FIG. 6;

FIG. 9 is a perspective view of a first alternative alignment structure of the automated test system of FIG. 1;

FIG. 10 is a perspective view showing an alignment rail of the first alternative alignment structure of FIG. 9;

FIG. 11 is a cross-sectional side view showing a second alternative alignment structure and a decoupling structure of the automated test system of FIG. 1;

FIG. 12 is a cross-sectional side view showing a third alternative alignment structure of the automated test system of FIG. 1; and

FIG. 13 is an end view showing a fourth alternative alignment structure of the automated test system of FIG. 1.

### DETAILED DESCRIPTION

While automated test systems for electronic components or devices are known, existing systems are not generally useful with respect to LEDs. Testing and sorting LEDs is particularly challenging because the wide variance in manufacturing tolerances and the sensitivity of the human eye to small variations in light output combine to require that LEDs be tested and sorted into a large number of output groups. While passive electronic devices might typically require five or ten output categories, LEDs might typically require in excess of 32 output categories up to as many as 512 categories. Other challenges associated with testing and sorting LEDs includes the fact that LEDs need to have their light output tested. Since LEDs can have contacts on one side of the package and light emitting surfaces on the other, the test equipment must probe from one side and collect light output from the other. Another challenge is that light output test equipment is often physically large and needs to be in proximity to the LED under test, which constrains the physical layout of the test equipment. In addition, if parallel testing is to be performed, where multiple test stations are arranged to test multiple devices simultaneously, room for multiple bulky optical test stations needs to be arranged.

The throughput achieved by an electronic device testing system depends upon the time required to test an electronic device as well as the time between successive tests. After a test is completed, a new electronic device is brought into registration with a test system at a testing workstation. If the time required for bringing the new device into registration with the testing system is reduced, throughput is increased. However, the electronic device must be accurately aligned with respect to the test system in order to allow the electronic device to be probed and to allow the response of the device to be monitored. These problems are exacerbated for LEDs due to their many testing requirements.

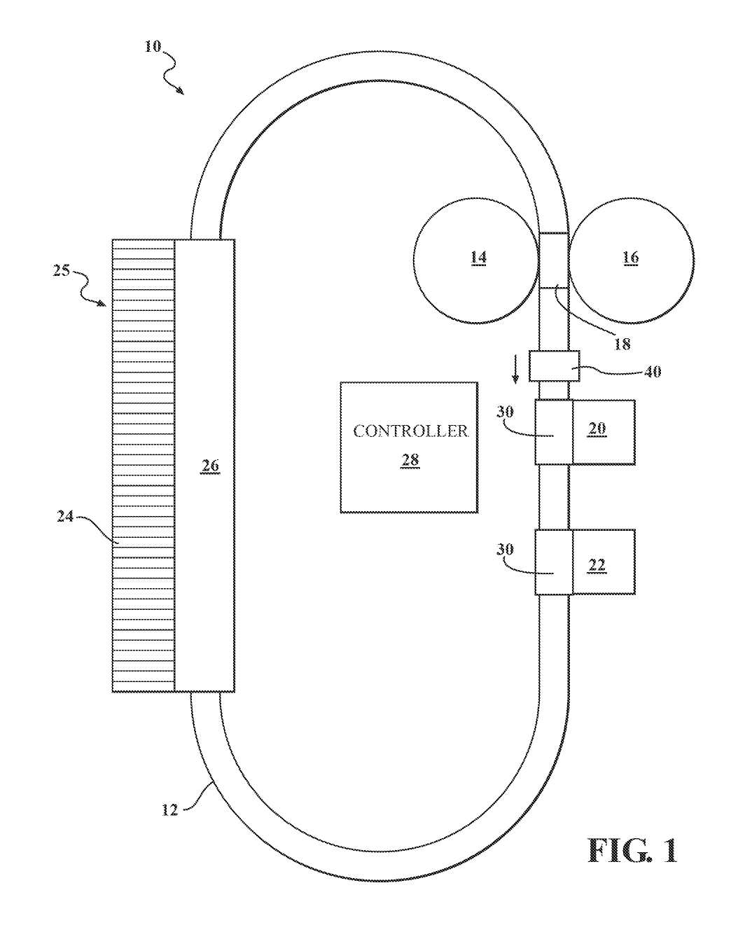

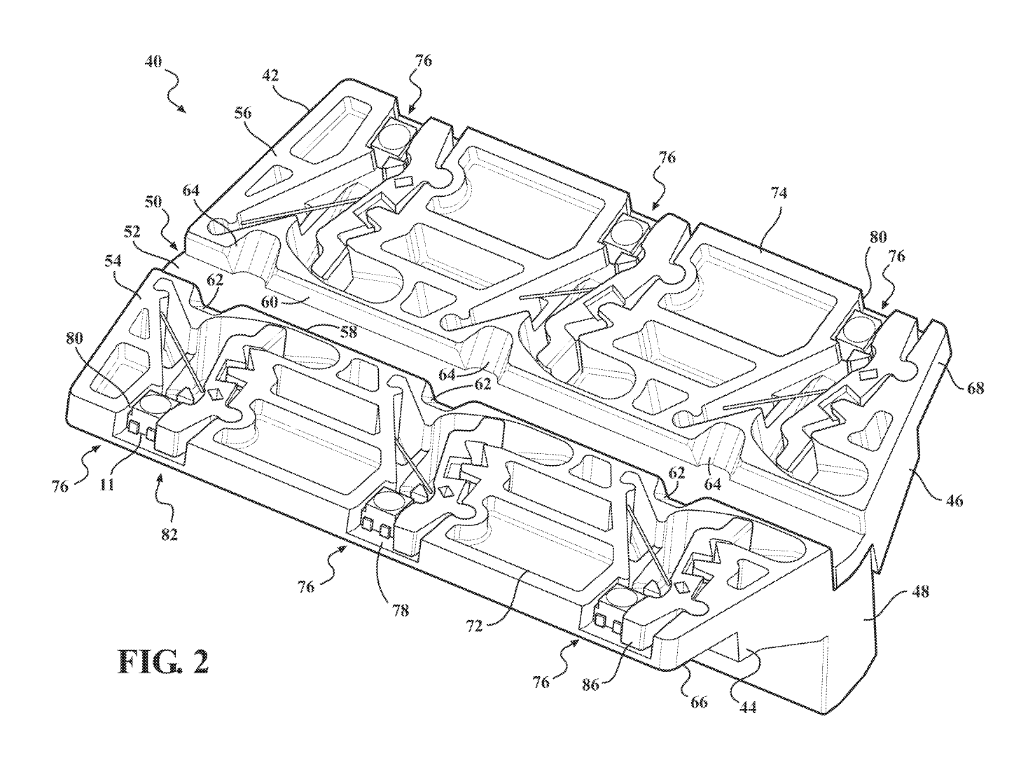

As described starting with respect to FIG. 1, embodiments of an automated test system 10 for testing and sorting of miniature electronic devices 11 (FIG. 2) taught herein provide a way of optimizing alignment so as to increase throughput. This is particularly desirable for devices 11 such as light emitting diodes (LEDs), that involve numerous tests.

Test system 10 includes a conveyor 12 and one or more loading stations, such as a first device loader 14 and a second optional device loader 16 that load electronic devices 11 onto carriers 40 at a transfer station 18. Test system 10 further includes one or more test stations, such as a first test station 20 and a second test station 22. Carriers 40 are aligned with respect to the first and second test stations 20, 22 by alignment structures 30 that are located at each of test stations 20, 22, as will be explained in detail herein. An unloading station 25 is provided to unload the devices. A controller 28 is in electrical communication, either wired or wireless, with conveyor 12, first and second device loaders 14, 16, first and second test stations 20, 22, and unloading station 25 to sense and control the operations of each.

Controller 28 has a conventional structure and may include a processor, memory, storage media, communications devices, and input and output devices. For example, controller 28 can be a standard microcontroller that includes a central processing unit (CPU), random access memory (RAM), read only memory (ROM) and input/output ports receiving input signals and sending output signals needed to control the system and to perform certain process steps as described herein. The functions described herein are generally programming instructions stored in memory and are performed by the logic of the CPU. Of course, the controller that performs the functions described herein could be a microprocessor using external memory or could comprise a combination of such a microprocessor or microcontroller combined with other integrated logic circuits. Controller 28 is generally incorporated into or works with a personal computer with a screen and input devices, such as keyboards, for inputting commands for process control and for monitoring the process control.

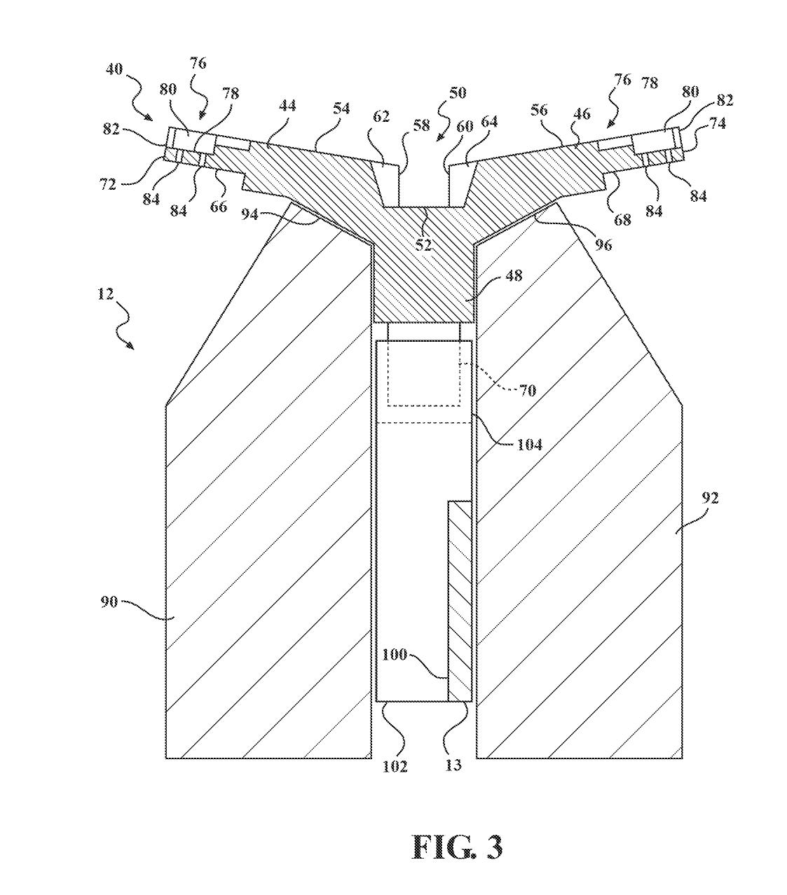

In order to test electronic devices 11 at one or both of first test station 20 and second test station 22, electronic devices 11 are loaded onto carriers 40 as shown in FIGS. 2 and 3. Each carrier 40 has a body portion, or body, 42 that may be fabricated as a one piece structure or a multiple piece structure. Body 42 includes a first lateral portion 44 and a second lateral portion 46 that extend outward from a central portion 48. First lateral portion 44 and second lateral portion 46 are spaced apart by a central channel 50. Central channel 50 is located above central portion 48. Central channel 50 includes a channel bottom surface 52 that is recessed downward with respect to a top surface 54 of first lateral portion 44 and a top surface 56 of second lateral portion 46. First and second channel sides 58, 60 extend upward from a channel bottom surface 52 to top surfaces 54, 56 of first and second lateral portions 44, 46, respectively.

One or more locating features or structures are formed on body 42 of carrier 40. For example, locating features could include pairs of first and second detents 62, 64. First detent 62 of each pair is formed along a first channel side 58 opposite second detent 64 of the pair, which is formed along a second channel side 60 opposite respective first detent 62. First detent 62 and second detent 64 are defined by surfaces that extend outward with respect to first and second channel sides 58, 60, thereby increasing the cross-sectional width of central channel 50 in the area of each pair of first and second detents 62, 64. Locating structures, such as first and second detents 62, 64 are provided to facilitate alignment of carrier 40 with respect to particular portions of test system 10, such as first test station 20 and second test station 22. Operation of locating structures will be explained in detail herein.

In carrier 40, central portion 48 of body 42 extends downward with respect to a bottom surface 66 of first lateral portion 44 and a bottom surface 68 of second lateral portion 46. Central portion 48 could be located directly below central channel 50 and could have a lateral width that is similar to the lateral width of central channel 50.

Carrier 40 is configured to be coupled to conveyor 12 such that carrier 40 moves in response to movement of conveyor 12. An engagement member 70 is formed on body 42 of carrier 40 for operable engagement of carrier 40 with conveyor 12. Engagement member 70 could be formed with any suitable geometry that allows engagement with conveyor 12. For example, engagement member 70 could be a downwardly extending tang, flange, projection, rod, post, hook, or any other suitable structure.

First and second lateral portions 44, 46 of body 42 respectively extend outward from central channel 50 to first and second lateral edges 72, 74 of body 42.

At least one device receptacle 76 is defined by body 42. For example, one or more of device receptacles 76 could be positioned along first and second lateral edges 72, 74 of body 42. Device receptacles 76 are recessed with respect to top surfaces 54, 56 of first and second lateral portions 44, 46 of body 42. For example, each device receptacle 76 could be defined by a substantially planar base surface 78 and one or more upstanding walls that are defined by first and second lateral portions of body 42, respectively. Each base surface 78 extends to one of first lateral edge 72 or second lateral edge 74 of body 42, thereby defining a lateral opening 82 for each device receptacle 76 along the respective one of first lateral edge 72 or second lateral edge 74. In order to allow testing of electronic devices 11, one or more probe holes are formed through body 42 in the area of each device receptacle 76. In particular, probe apertures or holes 84 could extend from base surface 78 of each device receptacle 76 to a respective bottom surface 66, 68 of either of first lateral portion 44 or second lateral portion 46, depending on the location of device receptacle 76. In the illustrated embodiment, four probe apertures 84 are provided for each device receptacle 76. However, the number of probe apertures 84 could be modified to suit a particular application.

In order to retain the electronic devices 11, carrier 40 may include a plurality of clamping structures 86. Clamping structures 86 could be provided in correspondence to device receptacles 76. For example, in the illustrated embodiment, a single clamping structure 86 is provided at each device receptacle 76. At least a portion of each clamping structure 86 biases into engagement with a respective one of electronic devices 11 in a manner that is suitable to clamp electronic device 11 with respect to body 42. For example, this could be done by capturing electronic device 11 in engagement between clamping structure 86 and one of upstanding walls 80 that defines a device receptacle 76. Other configurations could, however, be utilized.

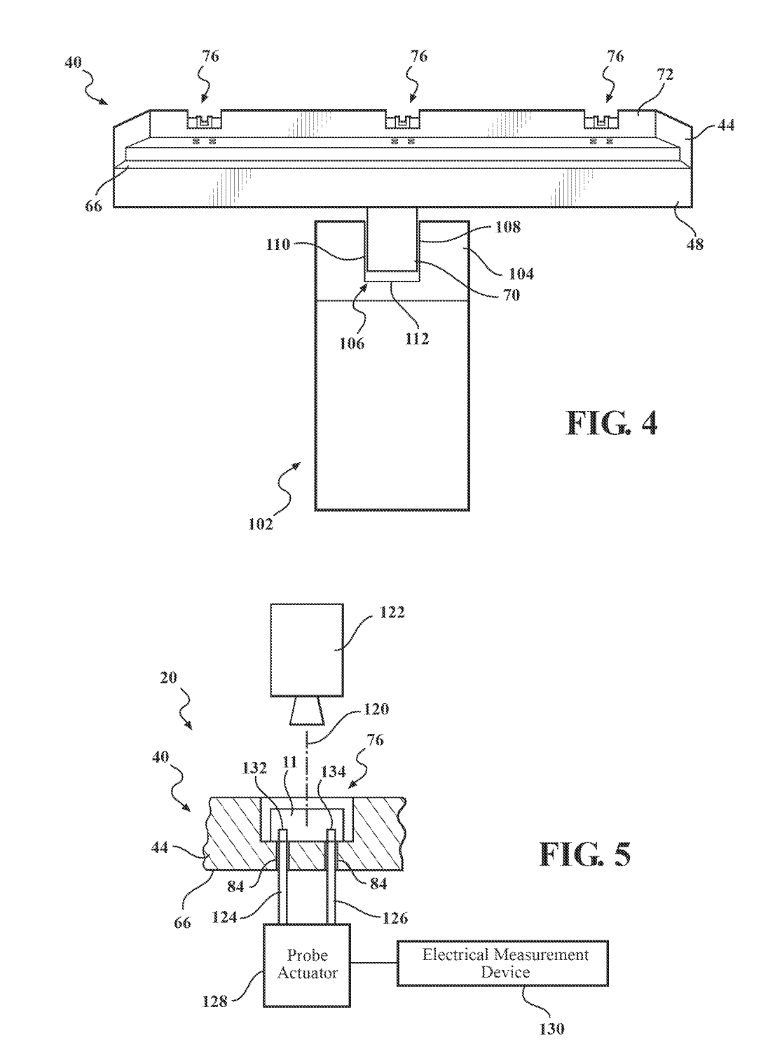

As shown in FIGS. 3 and 4, conveyor 12 is configured to support and move carriers 40 in a continuous circuit, and may be formed in any suitable geometry. Conveyor 12 could include a first rail 90 and a second rail 92 that are spaced apart with respect to one another. First and second rails 90, 92 include respective top surfaces 94, 96 that are configured to engage and support carrier 40. Top surfaces 94, 96 of first and second rails 90, 92 could be substantially continuous or could be non-continuous. Also, first and second rails 90, 92 could be provided with additional structures that engage and support the carriers, such as rollers (not shown).

A belt 13 is provided as the primary moving component of conveyor 12, such that objects that are moved by conveyor 12 are moved in correspondence to movement of belt 13. Although the description is made with reference to belt 13 as the primary moving component of conveyor 12, it should be understood that other suitable structures could be provided, such as a chain or cable.

Conveyor 12 is an indexing conveyor that indexes the position of belt 13 under the influence of a motor (not shown) or other suitable means. That is to say that belt 13 is moved in by a predetermined amount in a step-wise fashion, typically with a delay between successive movements. By way of example, this allows electronic devices 11 to be brought into registration with first and second test stations 20, 22, as will be described in detail hereinafter.

First and second rails 90, 92 of conveyor 12 extend around a circuit defined by conveyor 12, as does a belt 98 that is disposed between first and second rails 90, 92. A longitudinal direction of belt 98 is defined as the direction in which belt 98 extends around the circuit defined by conveyor 12.

Belt 98 is oriented such that a primary surface 100 of belt 98 is substantially upright. For example, belt 98 could be oriented such that a line constructed orthogonal to primary surface 100 of belt 98 extends in a direction that is generally horizontal.

Conveyor 12 includes a plurality of cleats 102 that are positioned at spaced locations with respect to one another along belt 98. Each cleat 102 is securely fastened to belt 98. In particular, each cleat 102 is in engagement with primary surface 100 of belt 98, and each cleat 102 can be fastened to belt 98 using fastening structures, such as screws, adhesives or other suitable means. The connection between each cleat 102 and belt 98 is such that the cleats 102 are not moveable with respect to belt 98, but rather, move in unison with belt 98 in a fixed relationship with respect thereto.

Each cleat 102 is configured to engage a carrier 40 such that carrier 40 moves in response to movement of belt 98 and cleat 102. This could be accomplished by providing a forked upper end 104 for each cleat 102. Forked upper end 104 of each cleat 102 defines a coupling recess 106 in which engagement member 70 of carrier 40 is received. With engagement member 70 disposed within coupling recess 106, indexing movement of belt 98 and cleats 102 causes engagement of forked upper end 104 of cleat 102 with engagement member 70, thereby moving carrier 40 in response to movement of belt 98 and cleat 102.

As shown in FIG. 4, coupling recess 106 of cleat 102 is defined by a first surface 108 and a second surface 110 that are longitudinally spaced with respect to one another. Longitudinally spaced first and second surfaces 108, 110 are generally upright and are spaced apart from one another by a base surface 112 that defines a bottom of coupling recess 106.

Engagement member 70 of carrier 40 is received within coupling recess 106 of cleat 102 such that a non-rigid coupling is established between carrier 40 and cleat 102. When engagement member 70 is received within coupling recess 106, a first surface 114 and a second surface 116 of engagement member 70 are respectively disposed adjacent to first and second surfaces 108, 110 of coupling recess 106. First and second surfaces 114, 116 may directly face first and second surfaces 108, 110 of coupling recess 106, respectively, and may be engageable therewith.

The non-rigid coupling between engagement member 70 and coupling recess 106 may be defined by providing a width between first and second surfaces 108, 110 of coupling recess 106 that is greater than a width between first and second surfaces 114, 116 of engagement member 70. The difference between these two widths defines a float distance along which carrier 40 is able to move with respect to cleat 102. In particular, if first and second surfaces 108, 110 of coupling recess 106, as well as first and second surfaces 114, 116 of engagement member 70 are all substantially orthogonal to a longitudinal direction of travel of carrier 40 along conveyor 12, the float distance would be established in the longitudinal direction of travel of carrier 40. Thus, carrier 40 is moveable with respect to conveyor 12 in the direction of travel of conveyor 12 by the float distance by virtue of movement of carrier 40 with respect to cleat 102.

Engagement member 70 and coupling recess 106 are exemplary first and second coupling parts by which carrier 40 could be non-rigidly coupled to cleat 102. It should be understood that other structures could be utilized. For example, the positions of the coupling recess 106 and engagement member 70 could be reversed, such that a portion of cleat 102 is received within a portion of carrier 40. Also, structures other than engagement members disposed in recesses could be provided. For example, one of carrier 40 and cleat 102 could be provided with an aperture, while the other is provided with a longitudinally extending rod that extends through that aperture. Of course, any other structure could be utilized so long as the non-rigid coupling between cleat 102 and carrier 40 described above results.

The float distance is established according to the needs of the system in question. In general, the float distance is selected in relation to the maximum distance by which carrier 40 could be moved with respect to cleat 102 in order to align carrier 40 in a desired position in the longitudinal direction. In an exemplary application, the float distance is on the order of 1-2 mm.

The non-rigid coupling between carrier 40 and cleat 102 allows alignment of carrier 40 with respect to a workstation, such as first test station 20 or second test station 22. As shown in FIG. 5, electronic device 11 is indexed into registration with or into the proximity of first test station 20. The indexing motion of conveyor 12 places electronic component 11 within a predetermined capture distance relative to an alignment axis 120 of first test station 20. In an exemplary system, this capture distance may be on the order of 1-2 mm, while an alignment tolerance on the order of 100 microns (+/−50 microns) is desired to allow testing of electronic component 11 of first test station 20. These distances serve as examples for purposes of explanation only, and the actual distances for the capture distance and alignment tolerance will vary by application.

By way of example, the test performed at first test station 20 may utilize an optical instrument 122 and a probe that includes a pair of test leads 124, 126, such as Kelvin connectors, that are moved into and out of probe apertures 84 of carrier 40 under the influence of a probe actuator 128. Test leads 124, 126 are in electrical communication with an electrical measurement device 130 for supplying a voltage to electronic device 11 and measuring electronic characteristics of electronic device 11. Optical instrument 122 could be configured to measure light that is emitted from electronic device 11 in response to voltage supplied by test leads 124, 126. Of course, other testing equipment could be provided in lieu of optical instrument 122, or it could be omitted.

An alignment axis 120 could be defined by the location of one or both of optical instrument 122 and test leads 124, 126. When electronic device 11 is brought into alignment with alignment axis 120, test leads 124, 126 are extended by probe actuator 128 such that they contact leads 132, 134 of electronic device 11 for testing by electrical measurement device 130. Additionally, alignment of electronic device 11 with respect to optical instrument 122 at alignment axis 120 allows, for example, the light emitted by electronic device 11 to be measured by optical instrument 122. It should be understood, however, that the configuration of first test station 20 is exemplary in nature, and that the principles explained with respect to first test station 20 could be applied to various types of workstations other that test stations to align devices such as electronic devices 11 with respect to the workstation.

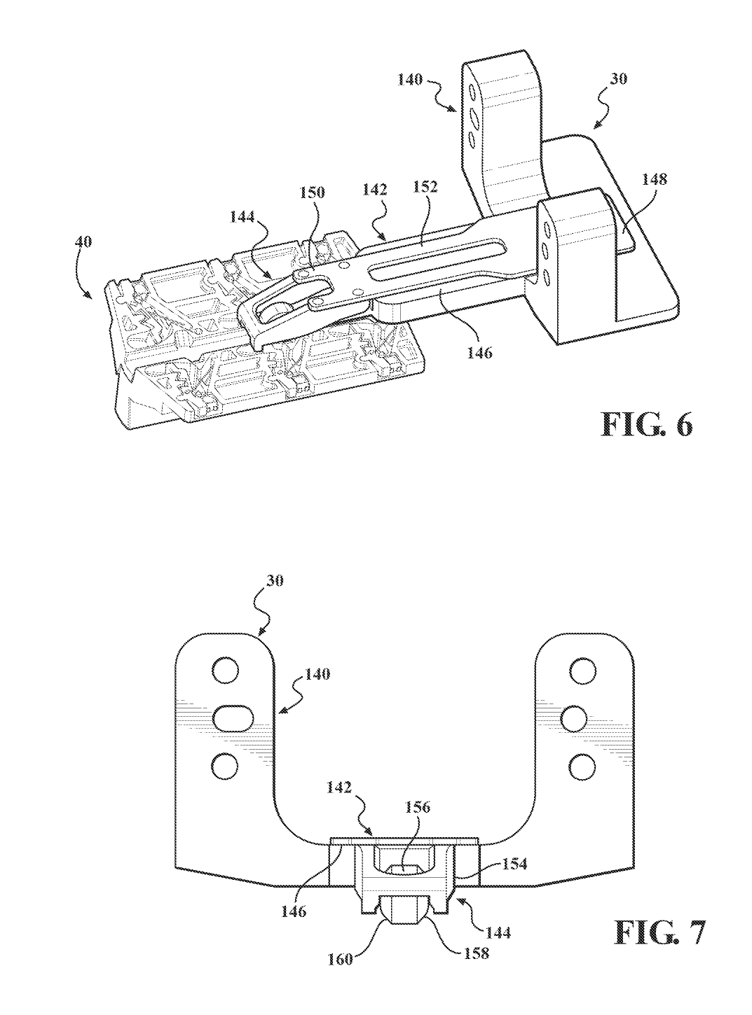

As mentioned above, in order to align electronic device 11 with respect to a workstation, such as first test station 20 or second test station 22, an alignment structure 30 may be provided at one or more of the workstations. As shown in FIGS. 6-8, alignment structure 30 includes a support member 140, a biasing member 142 and an engaging member 144.

Support member 140 of alignment structure 30 is adapted to support biasing member 142 and engaging member 144 at a fixed location above conveyor 12 and adjacent to one of the workstations, such as first or second test station 20, 22. Support member 140 is a substantially rigid structure and is fabricated from suitable rigid materials such as metals or plastics. Support member 140 could be a single piece structure or a multi piece structure and includes a surface 146 to which biasing structure 142 is connected. Surface 146 could be an upwardly facing surface.

Biasing member 142 is connected to support member 140 and engaging member 144 and serves to bias engaging member 144 toward engagement with carriers 40. Biasing member 142 could be a flat spring that extends from a first end 148 that is connected to surface 146 of support member 140 to a second end 150 that is connected to engaging member 144. An elongate intermediate portion 152 is located between first end 148 and second end 150 of biasing member 152 and may partly or completely overlie surface 146. As an example, surface 146 may be disposed opposite carriers 40 and connected to support member 140 such that it is able to deflect upward with respect to support member 140 in response to engagement with carriers 40. In such a configuration, engagement of biasing member 142 with surface 146 of support member 140 could serve to limit travel of engaging member 144 toward a carrier 40.

Second end 150 of biasing member 142 does not overlie surface 146 of support member 140 but rather is connected to engaging member 144. Engaging member 144 includes a yoke 154 that is adjacent to support member 140 and a roller 156 that is supported by yoke 154. Roller 156 has a first tapered side 158 and a second tapered side 160. First and second tapered sides 158, 160 of yoke 156 are engageable with first and second detents 62, 64 of carrier 40 in order to align carrier 40.

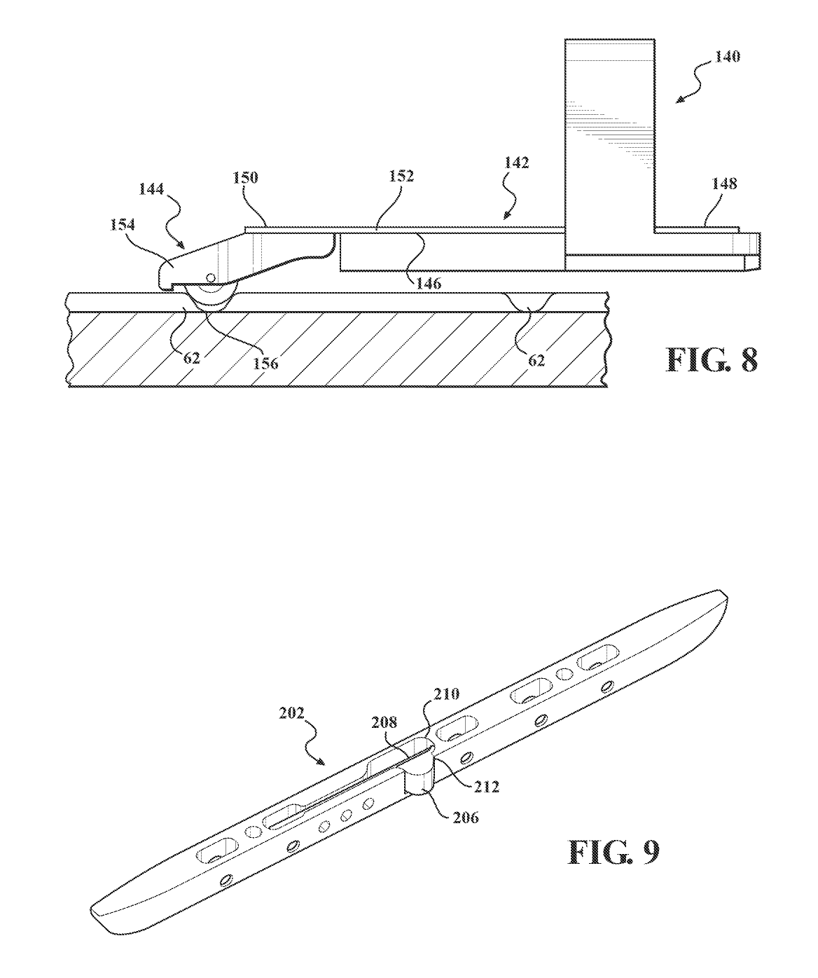

With reference to FIG. 8, when conveyor 12 indexes, one pair of first and second detents 62, 64 is moved into engagement with roller 156 of alignment structure 30. At this point, carrier 40 is within the predetermined capture distance, but may not be sufficiently aligned with respect to the workstation at which alignment structure 30 is installed. Engagement of roller 156 with first and second detents 62, 64, however, causes carrier 40 to move with respect to conveyor 12 such that a desired one of electronic devices 11 is moved into alignment with the workstation.

In order to cause movement of carrier 40 in response to engagement between roller 156 and first and second detents 62, 64, first and second detents 62, 64 are contoured complementary to first and second tapered surfaces 158, 160 of roller 156. The contour of first and second detents 62, 64 is selected to provide a desired level of positioning force. It will be understood that the positioning force derives from the spring force that is applied by biasing member 142 and that the contoured shape of detents 62, 64 translates this spring force into the positioning force, which moves carrier 40 with respect to conveyor 12 such that it is brought into alignment with the workstation.

Although alignment structure 30 has been described as including a roller 156 that engages first and second detents 62, 64 that are positioned along central channel 50 of carrier 40, it is contemplated that other alignment structures could be utilized. In particular, any structure capable of engaging carriers 40 to move carriers 40 longitudinally with respect to conveyor 12 could be utilized to align at least one electronic device 11 on carrier 40 with respect to a workstation such as first test station 20 or second test station 22.

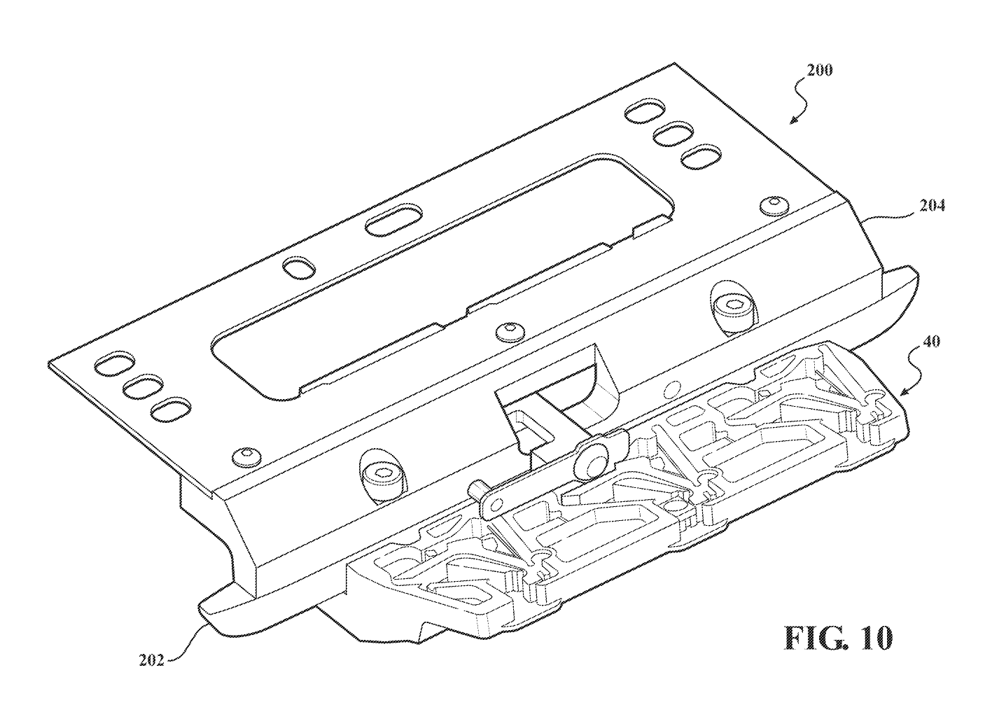

As shown in FIGS. 9 and 10, a first alternative alignment structure 200 includes an alignment rail 202 that is supported above conveyor 12 by a support structure 204 and depends downward from support structure 204. Alignment rail 202 extends in the longitudinal direction of conveyor 12 and is receivable within central channel 50 of carrier 40. Alignment rail 202 could have a length that is longer than carrier 40.

An engaging member 206 is connected to alignment rail 202 by a biasing member 208, such as a flat spring. Engaging member 206 is extendable out of a cavity 210 in alignment rail 202 through an aperture 212. When alignment rail 202 is disposed in central channel 50 of carrier 40 but is positioned such that engaging member 206 is not adjacent to one of first and second detents 62, 64, engaging member 206 is pushed into cavity 210 against the force applied by biasing member 208 by engagement with one of first channel side 58 or second channel side 60. When engaging member 206 is adjacent to one of first and second detents 62, 64, engaging member 206 extends out of cavity 210 through aperture 212 and into the respective one of first and second detents 62, 64 in response to the force applied by biasing member 208. Engaging member 206 is any structure suited for engagement with first and second detents 62, 64 to align carrier 40 such as, for example, a carbide nubbin or a roller.

As shown in FIG. 11, a second alternative alignment structure 300 includes a spring loaded arm 302 that supported by and pivots with respect to a fixed support structure 304 and includes an engaging member 306, such as a roller, that is biased into engagement with a carrier 308. Carrier 308 is similar to carrier 40, but differs in that detents 310 are positioned at longitudinally spaced locations along a channel bottom 312 of a central channel 314. As in previous embodiments, engagement of engaging member 306 with detents 310 functions to align carrier 308.

FIG. 11 also shows a conveyor 320 having cleats 322 that are configured to allow partial decoupling of carrier 308 with respect to conveyor 320. Cleats 320 each include a coupling recess 324 in the form of a variable width slot that has at least two distinct widths. For example, at least a portion of the surfaces that define each coupling recess could taper away from each other to widen coupling recess 324. Carrier 308 includes an engaging member 326 that is receivable within coupling recess 324 to define a first position of carrier 308 with respect to cleat 322, in which a first float distance is established, and a second position of carrier 308 with respect to cleat 322, in which a second float distance is established. The first float distance could be substantially zero, while the second float distance could be set according to the desired capture distance.

To at least partially decouple carrier 308 and cleat 322, a decoupling structure 326 is provided. Decoupling structure 326 is operable to move carrier 308 with respect to cleat 322 between the first and second positions, and may be any suitable structure capable of doing so. For example, decoupling structure 326 could be a structure that moves carrier 308 in an elevational direction, such as a deviation in the geometry of the rail geometry of conveyor 320, or a structure that moves carrier 308 elevationally with respect to conveyor 308. It should be understood that decoupling structure 326 could alternatively be configured to allow decoupling by lateral movement of carrier 308, or by transverse movement of carrier 308 with respect to conveyor 320 in any direction substantially orthogonal to the longitudinal direction.

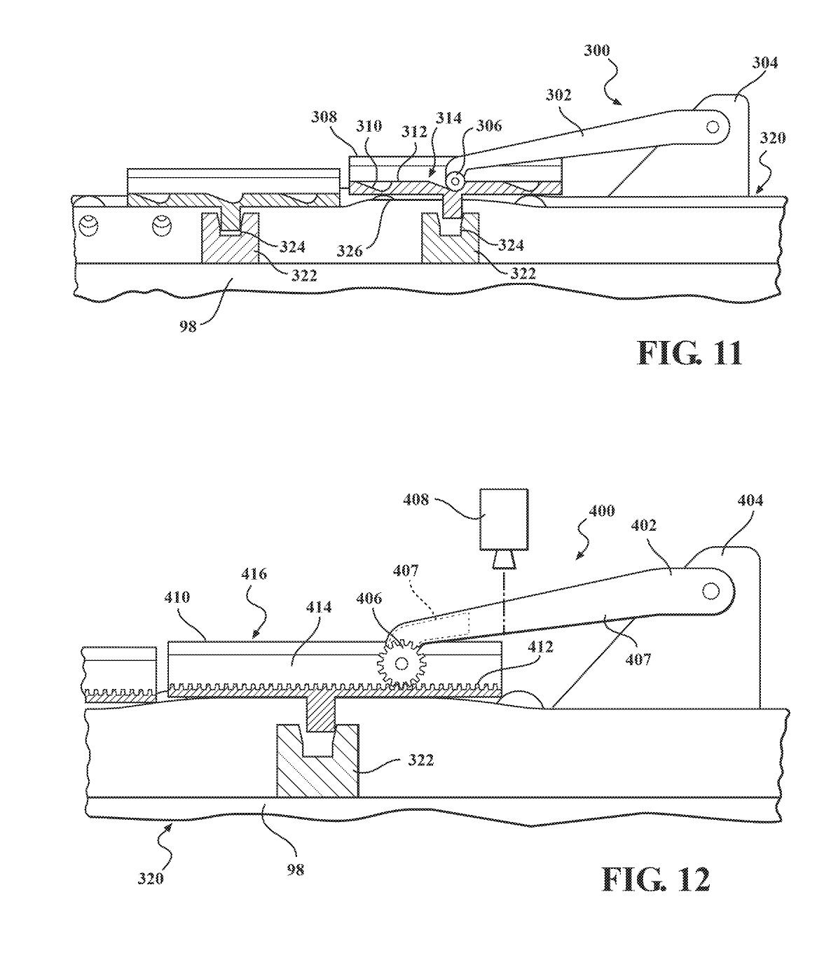

As shown in FIG. 12, a third alternative alignment structure 400 includes a spring loaded arm 402 that supported by and pivots with respect to a fixed support structure 404 and includes an engaging member in the form of a gear wheel 406 that is rotatable under power of an actuator assembly 407 in response to a sensor 408, such as an optical sensor of a machine vision system. A carrier 410 includes a gear rack 412 that is positioned along a channel bottom 414 of a central channel 416. Gear wheel 406 engages gear rack 412 and is actuated by actuator assembly 407 in response to sensor 408 to align a carrier 410.

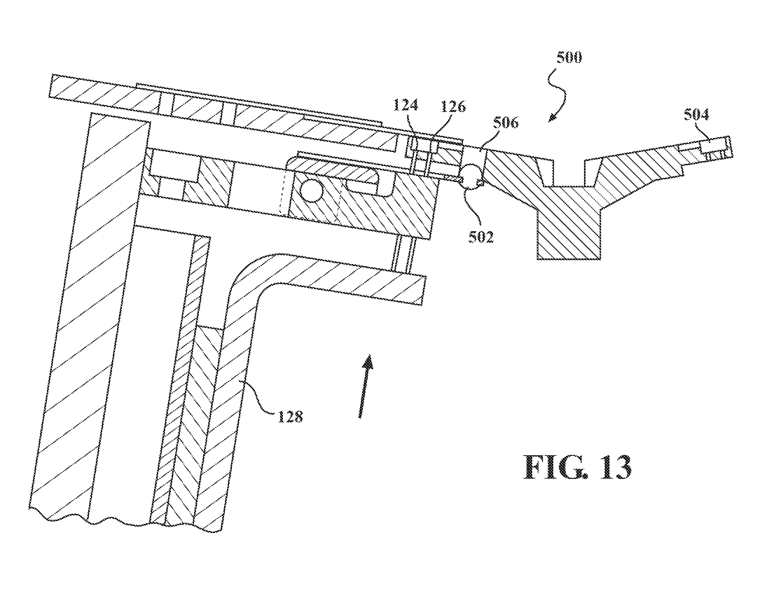

As shown in FIG. 13, a fourth alternative alignment structure 500 includes an engaging member in the form of a bullet-nosed locating pin 502 that aligns a carrier 504 by engagement with an aperture 506 in carrier 504. Locating pin 502 is actuated to move into engagement with carrier 504 after carrier 504 is indexed into position. For example, locating pin 502 could be mounted to probe actuator 128 for movement in unison with test leads 124, 126.

In operation, electronic devices 11 are loaded into the device loaders 14, 16, where they are singulated. Following singulation, the devices are transferred from device loaders 14, 16 to conveyor 12 at transfer station 18. Transfer station 18 is configured to move electronic devices 11 individually from device loaders 14, 16 to carriers 40 using mechanical or pneumatic means.

Conveyor 12 indexes, or moves a predetermined amount, which moves electronic devices 11 sequentially into proximity with first test station 20 and second test station 22. Devices 11 are aligned with respect to each of first and second test stations 20, 22 using alignment structures 30. First and second test stations 20, 22 may be configured to measure electronic devices 11 for parameters such as forward operating voltage and electrical current draw. By way of example, if electronic devices 11 are LEDs, they may also be measured for light output parameters such as luminous flux and spectral light output. This could be done, for example, using a spectrophotometer and an integrating sphere. An exemplary device which can perform these functions is the Model 616 Test and Measurement Source, manufactured by Electro Scientific Industries, Inc. of Portland Oreg.

Following testing, electronic devices 11 are unloaded at unloading station 25. Unloading station 25 can be configured to sort electronic devices 11 based on the results of the tests using a bin assembly 24 and an ejection assembly 26. Bin assembly 24 includes a large number of bins, and ejection assembly 24 ejects each electronic device 11 individually into a selected one of the bins of bin assembly 24 using, for example, selective application of pressurized air.

A typical cycle time for test system 10 contemplates a throughput of 32,000 devices per hour, which allows for a cycle time of 225 ms per device for each step in the process. In a typical system, conveyor 12 could be configured to index from one position to the next in 100 ms, leaving 125 ms for each step.

While the invention has been described in connection with certain embodiments, it is to be understood that the invention is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An alignment system for aligning one or more devices under test with respect to a test station, comprising:
a carrier that is configured to carry the one or more devices under test;
a conveyor that is configured to move the carrier in unison with the conveyor; and
an alignment structure that is engageable with the carrier to move the carrier with respect to the conveyor to align at least one of the devices under test with respect to the test station.

2. The alignment system of claim 1, wherein the carrier is non-rigidly connected to the conveyor, such that the carrier is moveable with the conveyor in response to movement of the conveyor, is moveable with respect to the conveyor in response to engagement of the alignment structure with the carrier, and remains moveable with the conveyor subsequent to engagement of the alignment structure with the carrier.

3. The alignment system of claim 1, wherein the conveyor includes a first coupling part and the carrier includes a second coupling part that is engageable with the first coupling part for moving the carrier in unison with the conveyor.

4. The alignment system of claim 3, wherein the conveyor moves the carrier in unison with the conveyor in a first direction, and the alignment structure moves the carrier with respect to the conveyor in the first direction.

5. The alignment system of claim 4, wherein the first coupling part is moveable with respect to the second coupling part in a second direction that is transverse to the first direction.

6. The alignment system of claim 5, wherein the first coupling part is moveable with respect to the second coupling part in the second direction between a first position, in which movement of the first coupling part with respect to the second coupling part is restrained by engagement of the first coupling part with the second coupling part, and a second position, in which the first coupling part is moveable with respect to the second coupling part in the first direction in response to engagement of the alignment structure with the carrier.

7. The alignment system of claim 6, further comprising:
a decoupling structure that is positioned along the conveyor adjacent to the test station and is engageable with the carrier to move the first and second coupling parts with respect to the first coupling part between the first position and the second position.

8. The alignment system of claim 7, wherein the decoupling structure moves the first and second coupling parts with respect to the first coupling part from the first position to the second position as the carrier arrives at the test station and moves the first and second coupling parts with respect to the first coupling part from the second position to the first position as the carrier departs from the test station.

9. The alignment system of claim 7, wherein the decoupling structure moves the first and second coupling parts laterally with respect to a rotation direction of the conveyor and between the first position to the second position.

10. The alignment system of claim 7, wherein the decoupling structure moves the second coupling part elevationally with respect to a rotation direction of the conveyor between the first position and the second position.

11. The alignment system of claim 7, wherein the first coupling part includes a variable width slot and the second coupling part is receivable within the variable width slot.

12. The alignment system of claim 1, wherein the carrier includes at least one locating feature and the alignment structure is engageable with the at least one locating feature to align the at least one of the devices under test with respect to the test station.

13. The alignment system of claim 12, wherein the alignment structure includes a spring loaded structure that is engageable with the at least one locating feature of the carrier to align the at least one of the devices under test with respect to the test station.

14. The alignment system of claim 12, wherein the alignment structure includes a locating pin that is engageable with the at least one locating feature of the carrier to align the at least one of the devices under test with respect to the test station.

15. The alignment system of claim 12, wherein the alignment structure includes a motor-driven gear wheel and the at least one locating feature of the carrier includes a gear rack; and wherein the motor-driven gear wheel is engageable with the gear rack to align the at least one of the devices under test with respect to the test station in response to rotation of the gear wheel.

16. The alignment system of claim 12, wherein the carrier includes a longitudinal channel, the at least one locating feature is positioned along the channel; and wherein the alignment structure includes and elongate member that is receivable within the channel of the carrier and a spring loaded structure that is disposed on the elongate member and is engageable with the at least one locating feature.

17. An alignment system for aligning one or more devices under test with respect to a test station, comprising:
a carrier that is configured to carry the one or more devices under test;
a conveyor that is configured to move the carrier in unison with the conveyor in a first direction;
a decoupling structure that is positioned along the conveyor adjacent to the test station and is engageable with the carrier to partially decouple the carrier from the conveyor such that the carrier is moveable with respect to the conveyor in the first direction; and
an alignment structure that is engageable with the carrier to move the carrier with respect to the conveyor to align at least one of the devices under test with respect to the test station when the carrier and the conveyor are partially decoupled.

18. The alignment system of claim 17, wherein the conveyor includes a first coupling part, the carrier includes a second coupling part that is engageable with the first coupling part for moving the carrier in unison with the conveyor, and the decoupling structure is configured partially decouple the carrier from the conveyor by moving the second coupling part with respect to the first coupling part in a second direction that is substantially transverse to the first direction.

19. The alignment system of claim 17, wherein the decoupling structure partially decouples the carrier from the conveyor as the carrier arrives at the test station and re-couples the carrier to the conveyor as the carrier departs from the test station.

20. A system for aligning one or more devices under test with respect to a test station, comprising:
a carrier that is configured to carry the one or more devices under test, wherein the carrier includes at least one locating feature;
a conveyor that is configured to move the carrier in unison with the conveyor in a first direction;
a decoupling structure that is positioned along the conveyor adjacent to the test station and is engageable with the carrier to partially decouple the carrier from the conveyor such that the carrier is moveable with respect to the conveyor in the first direction, wherein the decoupling structure partially decouples the carrier from the conveyor as the carrier arrives at the test station and re-couples the carrier to the conveyor as the carrier departs from the test station; and
an alignment structure that is engageable with the at least one locating feature of the carrier to move the carrier with respect to the conveyor to align at least one of the devices under test with respect to the test station.
